(19) United States
(12) Patent Application Publication
(10) Pub. No.: US 2012/0280133 A1
(43) Pub. Date: Nov. 8, 2012

(54) NEUTRON DETECTOR HAVING PLURALITY OF SENSING ELEMENTS

(75) Inventors: Danny R. Kagey, Columbia, MD (US); Walter William Heikkila, Burnsville, MN (US); Allan Thomas Hurst, JR., Anoka, MN (US)

(73) Assignee: TRUSTED SEMICONDUCTOR SOLUTIONS, INC., Anoka, MN (US)

(21) Appl. No.: 13/463,529

(22) Filed: May 3, 2012

Related U.S. Application Data
(60) Provisional application No. 61/482,037, filed on May 3, 2011.

(51) Int. Cl. G01T 3/08; H01L 31/119

(52) U.S. Cl. 250/370.05; 257/252; 257/E31.091

(57) ABSTRACT

A neutron detector and method are provided. The detector includes a neutron conversion material that emits charged particles in response to a reaction with neutrons, a plurality of semiconductor sense elements that are sensitive to the charged particles, and a latch coupled to an output of semiconductor sense elements.

### CROSS-REFERENCE TO RELATED APPLICATIONS

The present application is based on and claims the benefit of U.S. Provisional Patent Application No. 61/482,037, filed May 3, 2011, the content of which is hereby incorporated by reference in its entirety.

### STATEMENT REGARDING FEDERALLY SPONSORED RESEARCH OR DEVELOPMENT

None.

### THE NAMES OF PARTIES TO A JOINT RESEARCH AGREEMENT

None.

### FIELD OF THE DISCLOSURE

The present disclosure is directed in general to a neutron detection device. A specific example of the present disclosure is directed to a semiconductor device for detection of neutrons, which utilizes a neutron conversion layer in close proximity to charge-sensitive semiconductor devices.

### BACKGROUND OF THE DISCLOSURE

The detection of radioactive material is of critical importance for applications such as monitoring safety of nuclear power plants and detecting the transport of nuclear materials by unauthorized individuals.

Nuclear materials emit several types of radiation, such as alpha particles, beta particles, gamma rays, and neutrons. Neutrons may be the only type of radiation that can be detected from nuclear material that is insulated by a lead shield since neutrons are capable of passing through the lead shield. However, these neutrons can be difficult to detect since neutrons are non-charged particles that may not interact directly with electronic sensing devices.

Silicon-based semiconductor devices have been proposed recently to sense alpha particles emitted from a neutron converter material in response to an n. alpha reaction. The converter material converts incident neutrons into emitted charged particles, which are more readily sensed in a semiconductor diode structure. Such devices therefore serve as neutron detectors. These diode structures, however, can have a high level of internal noise, which can make it difficult to measure low levels of neutrons or to detect single neutron events.

In addition, it has been proposed to use a commercial memory circuit with a neutron converter to detect a Single Event Upset (SEU) particle reaction. Y. As described in Y. Arita et al., “Experimental Investigation of Thermal Neutron-Induced Single Event Upset in Static Random Access Memories,”, Jpn. J. Appl. Phys. 40, pp L151-153 (2001), ¹⁰B in the dopant or borophophosilicate glass (BPSG) passivation layer sensitizes a circuit to neutron radiation. Based on this sensitivity, Houssain U.S. Pat. No. 6,075,261 suggests using a conventional semiconductor memory structure as a neutron detector, wherein a neutron-reactant material (a converter such as boron) is coated over a conventional flash memory device. In this proposal, alpha particles emitted by the boron pass through the structural layers of the circuit before they reach the active semiconductor. This limits the resulting charge in the active semiconductor layer for detecting a single event upset.

August et al. U.S. Pat. No. 7,271,389 and Hughes U.S. Pat. No. 6,867,444 disclose a neutron detection device that utilizes a neutron conversion layer in close proximity to charge-sensitive elements such as conventional memory cells. The device provides the neutron conversion layer in close proximity to the active semiconductor layer of the memory cells. This location increases the sensitivity of the neutron detection device.

### SUMMARY

An illustrative aspect of the present disclosure relates to a neutron detector. The detector includes a neutron conversion material that emits charged particles in response to a reaction with neutrons, and a sensor comprising a plurality of semiconductor sense elements electrically connected together in parallel, which are sensitive to the charged particles. A latch is coupled to an output of the sensor.

In a particular example, the plurality of semiconductor sense elements includes a plurality of reverse-biased semiconductor junctions coupled together in parallel.

In a particular example, the plurality of semiconductor sense elements includes a plurality of P-channel or N-channel transistors coupled together in parallel and biased in an “OFF” state.

In a particular example, the latch includes cross-coupled inverters having first and second nodes of opposite logic states. The sensor includes a first plurality of charge-sensitive P-channel transistors coupled together in parallel and having a first output connected to the first node of the latch, and a second plurality of charge-sensitive N-channel transistors coupled together in parallel and having a second output connected to the second node of the latch.

In another particular example, the sensor includes a plurality of transistors coupled together in parallel between a voltage bias node and the output and biased in an “OFF” state, which blocks current from flowing between the voltage bias node and the sensor output. Each of the transistors includes a body and a parasitic transistor having a parasitic current-control terminal formed by the body, which is configured to become forward biased in response to the charged particles.

In a particular example, the neutron detector further includes a first voltage bias node. The sensor includes a plurality of transistors coupled together in parallel with one another. Each transistor includes a first terminal connected to the first voltage bias node, a second terminal connected to the sensor output, and a third, current-control terminal, which controls current flow between the first and second terminals and is coupled to the first voltage bias node.

In a particular example, the neutron detector further includes first and second voltage bias nodes and the plurality of semiconductor sense elements includes a plurality of N-type or P-type transistors coupled together in parallel with one another. Each transistor includes a first terminal connected to the first voltage bias node, a second terminal connected to the sensor output, and a third, current-control terminal, which controls current flow between the first and second terminals and is coupled to the second voltage bias node. In the case of the plurality of transistors being N-type transistors, the second voltage bias node is biased at a more negative voltage than the first voltage bias node. In the case of the plurality of transistors being P-type transistors, the second voltage bias node is biased at a more positive voltage than the first voltage bias node.

In a particular example, the latch includes a control input, cross-coupled inverters having first and second nodes of opposite logic states, and first and second bit lines. A first pass gate is coupled between the first node and the first bit line, and a second pass gate is coupled between the second node and the second bit line, the first and second pass gates having control terminals coupled to the control input.

In a particular example, the conversion material includes a material that emits at least one of alpha particles or Lithium ions in response to a neutron passing through the conversion material.

In a particular example, the neutron detector of claim 1, further includes a plurality of sensors and a plurality of respective latches. Each sensor includes a plurality of semiconductor sense elements that are connected together in parallel, are sensitive to the charged particles, and have a corresponding output. Each latch is coupled to the output of a respective one of the sensors.

Another aspect of the present disclosure relates to a semiconductor substrate including a neutron conversion layer that emits charged particles in response to a reaction with neutrons and an active semiconductor device layer having at least one latch with a latch input. A plurality of semiconductor sense elements, which are sensitive to the charged particles, are connected to the latch input.

Another aspect of the present disclosure relates to a method of detecting a neutron. The method includes: emitting charged particles from a neutron conversion material in response to a reaction of the neutron conversion material to a neutron; initializing a latch to a first state; biasing a plurality of semiconductor sense elements in an OFF state, the semiconductor sense elements being configured to produce a sense current in response to the charged particles; changing the latch from the first state to a second, different state using the sense current; and reading a present state of the latch to detect the change from the first state to the second state.

### BRIEF DESCRIPTION OF THE DRAWINGS

FIG. 1 is a simplified cross-sectional view, which schematically illustrates a semiconductor integrated circuit device according to an exemplary embodiment of the present disclosure.

FIGS. 2A and 2B are diagrams of PMOS and NMOS transistors with associated parasitic bipolar transistors.

FIG. 2C illustrates a cross-sectional view of a PMOS transistor and its parasitic bipolar transistor.

FIG. 3 is a block diagram illustrating a neutron detection circuit according to an illustrative aspect of the disclosure.

FIG. 4 is a schematic diagram illustrating in more detail an example of the neutron detector circuit shown in FIG. 3, according to a particular example of the present disclosure.

FIG. 5 is a diagram illustrating an exemplary physical layout of the neutron detection circuit shown in FIG. 4.

FIG. 6 illustrates a schematic diagram of a neutron detection circuit having first and second sensors containing NMOS and PMOS charge-sensitive elements, respectively, according to an alternative embodiment of the disclosure.

FIG. 7 illustrates a simulation file of the circuit shown in FIG. 4.

FIG. 8 is a simulation plot of a hit on a single element in the charged particle sensor shown in FIG. 4.

FIG. 9 is a simplified cross-sectional view of a neutron sensitive semiconductor integrated circuit device in which the neutron conversion layer is located between the active semiconductor layer and the base substrate.

FIG. 10 is a simplified cross-sectional view of a neutron sensitive semiconductor integrated circuit device in which the plurality of sensing elements is positioned on a different layer than the active semiconductor devices that form the capture latch.

FIG. 11 is a diagram illustrating an example of a possible architecture of a neutron detection chip according to the present disclosure.

### DETAILED DESCRIPTION OF ILLUSTRATIVE EMBODIMENTS

The following is provided as a description of examples of one or more aspects of the present disclosure. The below detailed description and above-referenced figures should not to be read as limiting or narrowing the scope of the invention as will be claimed in issued claims. It will be appreciated that other embodiments of the invention covered by one or more of the claims may have structure and function which are different in one or more aspects from the figures and examples discussed herein, and may embody different structures, methods and/or combinations thereof of making or using the invention as claimed in the claims, for example.

Also, the following description is divided into sections with one or more section headings. These sections and headings are provided for ease of reading only and, for example, do not limit one or more aspects of the disclosure discussed in a particular section and/or section heading with respect to a particular example and/or embodiment from being combined with, applied to, and/or utilized in another particular example, and/or embodiment which is described in another section and/or section heading. Elements, features and other aspects of one or more examples may be combined and/or interchangeable with elements, features and other aspects of one or more other examples described herein.

Embodiments of the present disclosure can be used in a variety of different applications of neutron detectors and housed in a variety of different types of apparatus.

### 1. Introduction

Recent technology advancements have produced a neutron sensor that employs a neutron conversion material such as Boron 10 or Lithium Fluoride that interacts with neutrons. An interaction between a neutron and the conversion material such as a Boron 10 atom will generate a Lithium ion and an alpha particle. The Lithium ion and/or alpha particle are then sensed by a charge sensitive element, such as a charge-sensitive semiconductor device that is sensitive to their deposited energy levels.

An illustrative embodiment of the present disclosure relates to improving the sensing capacity per unit area of the neutron detector device. For example, an array of sensing elements electrically connected in parallel with one another is configured with a single latching block. This structure may be duplicated to form a neutron detector on an integrated circuit, which significantly increases the collection efficiency/cm² over previously tried conventional SRAM memory cells. Such a neutron detector is applicable, for example, in various semiconductor processes, such as but not limited to Silicon-on-Insulator (SOI) processes, for example 90 nm, 65 nm, 45 nm, 32 nm and below SOI processes.

In at least one particular example of the present disclosure, the neutron detector device does not require the use of high pressure tubes or high voltages, is not sensitive to gamma radiations, is not sensitive to thermal noise, and operates with low enough power consumption for extended battery life, but yet is sensitive enough to permit the counting of single neutron events.

An exemplary neutron detector device of the present disclosure is inexpensive to design and manufacture. Such an exemplary device may be employed in many form factors with excellent detector efficiency/cm² and excellent static power/cm² such that larger arrays can be built economically with commercial processing, eliminating dependence on more exotic detection materials. Low operating voltages may reduce power and operating costs and may provide the opportunity for battery powered remote operation. In a particular example, the neutron detector device is fabricated with metal-oxide semiconductor technology and has a latch detection element that can provide a direct digital interface to microprocessor monitoring systems, for example.

The combination of detection efficiency, low operating voltage and current, long operating battery life, remote operation, very small form factor, and low manufacturing cost allows an example of the neutron detector to be manufactured in a product form to meet needs that have not been even considered with present technologies.

### 2. Example Embodiment of a Neutron Sense Element

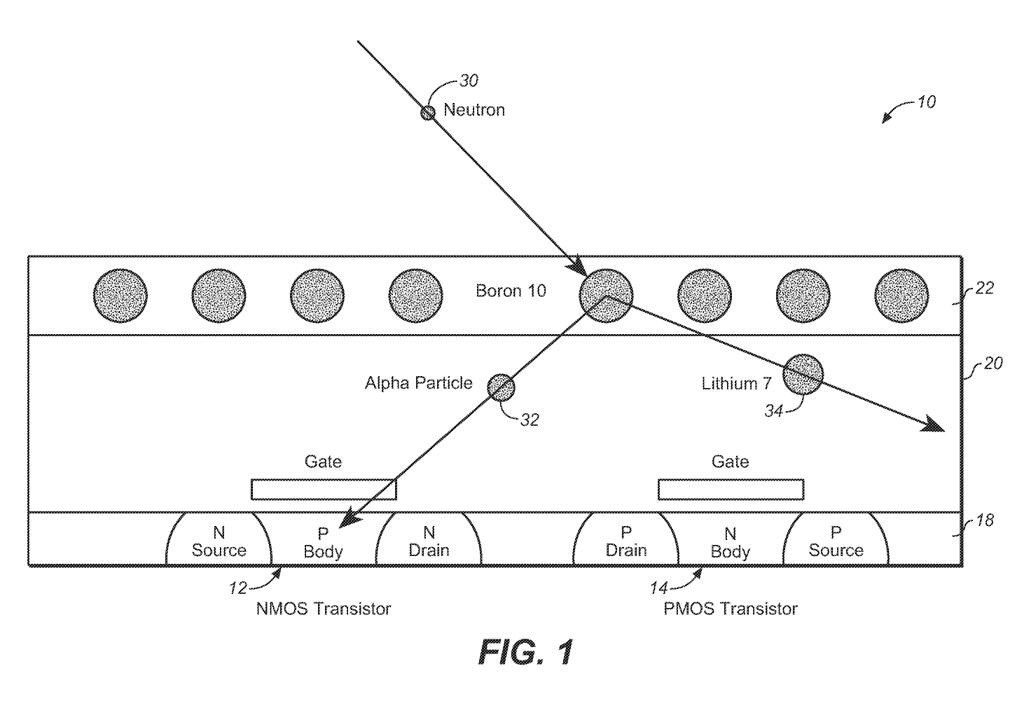

FIG. 1 is a simplified cross-sectional view, which schematically illustrates a semiconductor integrated circuit device and the basic operation of a neutron detection event according to an exemplary embodiment of the present disclosure. In this example, semiconductor integrated circuit device 10 includes one or more metal oxide semiconductor (MOS) transistors 12 and 14. The semiconductor elements of transistors 12 and 14 are fabricated within an active semiconductor layer 18. An interconnect layer 20 includes various individual layers and elements that electrically interconnect the semiconductor devices in a pattern to form a desired circuit configuration. These interconnect elements can include, for example, polysilicon interconnects, metal layers, vias between layers, insulating layers, etc. A neutron conversion layer 22 is positioned in close proximity to the MOS transistors in active semiconductor layer 18. The neutron conversion layer includes a neutron conversion material comprising any suitable material that emits charged particles in response to a reaction with neutrons. For example, the neutron conversion layer can include materials such as Boron and/or Lithium. In a specific example, the material includes Boron-10 or Lithium-6.

The neutron conversion layer 22 can be located in a variety of different locations on or between various layers within semiconductor device 10. In this example, the neutron conversion layer 22 is fabricated on top of one or more of the interconnect layers 20. For example, the neutron conversion layer may be fabricated on top of (or in replace of) a passivation layer. In another example, neutron conversion layer 22 is located below the active semiconductor layer 18, such as below a silicon dioxide insulating layer that is adjacent active semiconductor device layer 18 in a silicon-on-insulator example of integrated circuit 10. Various insulating layers and/or barrier layers can also be used relative to conversion layer 22 and the other layers of device 10.

Since a neutron has no electrical charge, the presence of the neutron cannot be sensed directly by an electronic circuit. However, a neutron does have a nuclear interaction with certain elements, such as a Boron10 atom in which two charged particles are created. The interaction creates an alpha particle and a Lithium ion with Linear Energy Transfer (LET) values of 1.47 and 0.84 (MeV-cm²/mg) respectively, as shown in FIG. 1. As a neutron 30 transits device 10, the nuclear interaction between the neutron and conversion layer creates an alpha particle 32 and a Lithium ion 34. If one of these particles passes through charge-sensitive device, such as a biased semiconductor junction, the energy of such a charged particle can create a charge in the junction due to hole-electron pair generation. This charge can then be detected by circuitry coupled to the semiconductor junction. In the example shown in FIG. 1, alpha particle 32 passes through the body of transistor 12, which is sensitive to the charge carried by alpha particle 32 and Lithium ion 34.

Examples of suitable charge-sensitive elements include but are not limited to biased semiconductor junctions, such as P-type or N-type MOS transistors formed on a silicon-on-insulator (SOI) substrate. Other charge-sensitive elements and devices can also be used, such as other semiconductor materials. The neutron conversion material can include any material that emits charged particles in response to a reaction with neutrons, such as material based on Boron and/or Lithium. In the case of Boron, these charged particles can include alpha particles and Lithium ions, for example. In the case of Lithium, these charged particles can include tritons, for example. Examples of other neutron conversion materials include proton emitters and electron emitters.

As described below with reference to a particular embodiment, a plurality of these neutron sense elements (i.e., biased semiconductor junctions) is arranged in an array, which generates a signal (e.g., a voltage change) that can be captured by a latch circuit. The latch circuit has a critical charge, Qcrit, which is the amount of charge generated in the sense element to provide a sufficient signal to change the state of the latch.

The charge that can be deposited in a semiconductor junction is determined by the LET of the ion, the material density, and the junction dimensions. Based on the minimum Qcrit of the Lithium ion, a sense element can be designed that converts the Qcrit into a digital signal level. Since the LET of the alpha particle is higher, it will also be captured, which increases efficiency by detecting of both alpha particles and Lithium ions. The design and optimization of the sense element may be performed in conjunction with the design of the latch, since the latch has to change state upon the sense element signal.

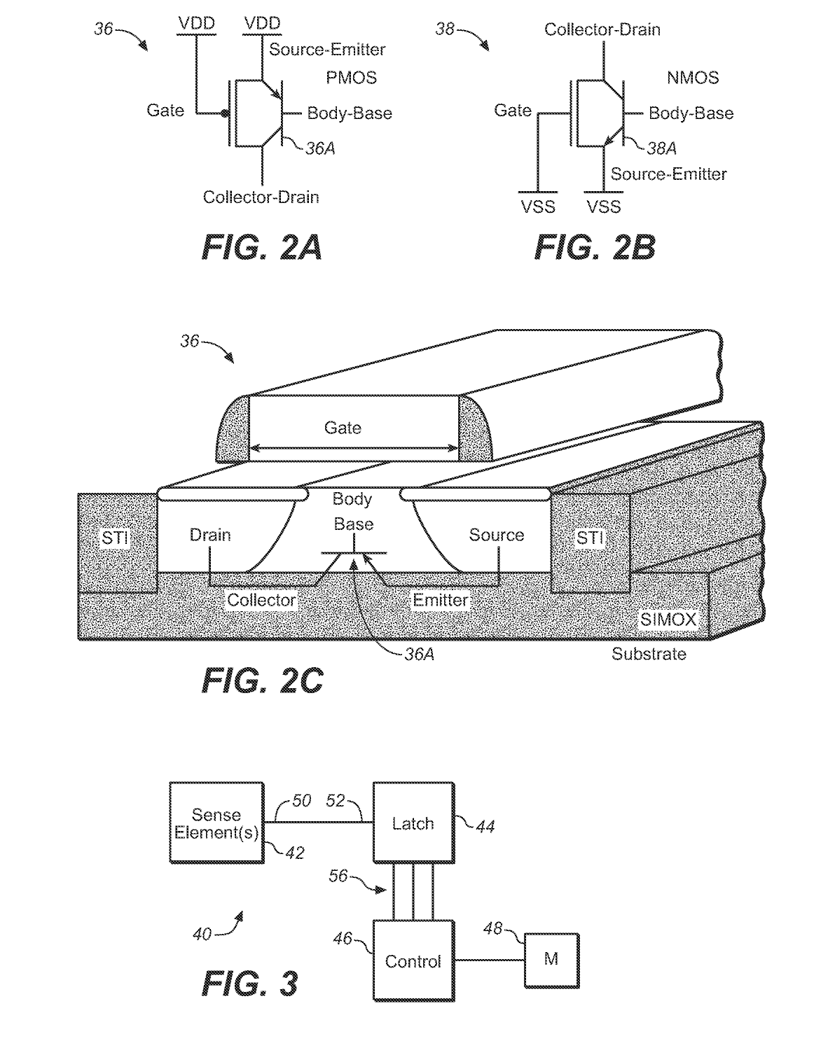

The specific ion sense mechanism is now described for the example of a PMOS transistor 36, shown in FIG. 2A, and an NMOS transistor 38, shown in FIG. 2B. A MOS transistor has four nodes: a source, a gate, a drain and a body. The gate forms a current-control terminal, which controls current flow between the source and drain. MOS transistors 36 and 38 also form parasitic bipolar transistors 36A and 38A, respectively, in which the body forms a parasitic, current-control terminal referred to as a base, and the source and drain form an emitter and a collector of the parasitic bipolar transistor. In normal semiconductor logic operation these parasitic bipolar devices 36A and 38A are reverse-biased such that their negative effects are minimized. FIG. 2C illustrates a cross-sectional view of PMOS transistor 36 and its parasitic bipolar device 36A.

During normal MOS operation when the gate voltage is in the “on” state, transistors 36 and 38 become forward-biased and have low resistance between source and drain, which permits current to flow between the source and drain. When the gate voltage in the “off” state, the source to drain resistance is high, which prevents current from flowing between the source and drain. The parasitic bipolar transistor, 36A or 38A, is not active during normal circuit operation. However if a large enough charge is deposited by an alpha particle or a Lithium ion into the body region of an “off” MOS transistor, the charge can turn the parasitic bipolar transistor “on” into a conductive state. The resulting current that flows between the source and drain, which in this case is from the parasitic bipolar transistor in the MOS structure, can be used to change the state of a latch circuit.

Referring to FIG. 2A, PMOS transistor 36 can be configured as a neutron sense element by connecting the source-emitter to a positive power supply terminal VDD and connecting the gate to either the positive power supply terminal VDD or a power supply having a higher voltage than VDD. The drain can be connected to the latch input to provide a sense signal to change the state of the latch. An ion hit to the body-base region of PMOS transistor 36 will cause the base-emitter junction to forward bias and turn “on” the parasitic pnp transistor, thus providing the sense signal to the latch.

Referring to FIG. 2B, NMOS transistor 38 can be configured as a neutron sense element by connecting the source-emitter to a ground voltage and connecting the gate to either the ground supply terminal VSS or a voltage terminal that is lower (or more negative) than VSS. The drain can be connected to the latch input to provide a sense signal to change the state of the latch. An ion hit to the body-base region of NMOS transistor 38 will cause the base-emitter junction to forward bias and turn “on” the parasitic npn transistor, thus providing the sense signal to the latch.

Circuit models of the bipolar operation have been imbedded into basic MOS transistor models that are used by designers for circuit emulation. These models incorporate the physical dimensions such as oxide thickness, gate width, and gate length. Electrical characteristics such body resistance, gate leakage, junction leakage, sub-threshold leakage, junction capacitance, and gate capacitance are also included.

Along with the circuit models, a set of transient “hit models” that emulate the charge deposition in the bipolar base region can be used to predict electrical performance of a biased semiconductor junction as an ion sense element. Detailed circuit design of the sense element can involve a matrix of simulations that vary transistor sizes, charge deposition, temperature, voltage, transistor thresholds and circuit configurations, for example. The particular design of a sense element should provide a detectable signal to a latch (or other detection circuit) after an alpha particle hit or a Lithium ion hit.

### 3. Neutron Sense Latch

FIG. 3 is a block diagram illustrating a neutron detection circuit 40 according to an illustrative aspect of the disclosure. Neutron detection circuit 10 includes a charged particle sensor 42, a detection latch 44 and a control circuit 46. Charged particle sensor 42 and latch 44 are fabricated on a semiconductor integrated circuit die, and all or part of control circuit 46 can be fabricated on the same die or on a separate die or circuit.

Charged particle sensor 42 includes a plurality of charge-sensitive sense elements (for example biased semiconductor junctions) that are configured to detect charged particles emitted by a neutron conversion material, such as in the manner discussed with reference to FIGS. 1 and 2, and provide a signal on sense output 50 indicative of the hit. Sense output 50 is electrically coupled to latch input 52. Upon detection of a charged particle, one or more of the sense elements in sensor 42 deposits a charge onto (or removes a charge from) sense output 50, which changes the state of latch 44. The resulting change in the logic state can then be read by control circuit 46.

As discussed in more detail below, control circuit provides a set of control signals 56 to latch 44, which control the operating modes of latch 44 and permit the state of the latch to be read. For example, control circuit 46 supplies control and voltage bias inputs to operate latch 44 in a “set” mode, a “sense” mode and a “read” mode. In the set mode, control circuit 46 sets latch 44 to an initial state. In the sense mode, control circuit 46 biases transistors in latch 44 such that charge deposited onto latch input 52 (or charge removed from latch input 52) by sense elements 42 will change the state of the latch from the “set” state to a “reset” state. The “set” and “reset” states can correspond to suitable logic levels, such as high and low, or low and high, respectively, depending on the circuit configuration. In addition, various transistors in latch 44, itself, are biased to detect the charged particles and upset the state of latch 44. In the “read” mode, control circuit biases transistors in latch 44 to read the state of the latch.

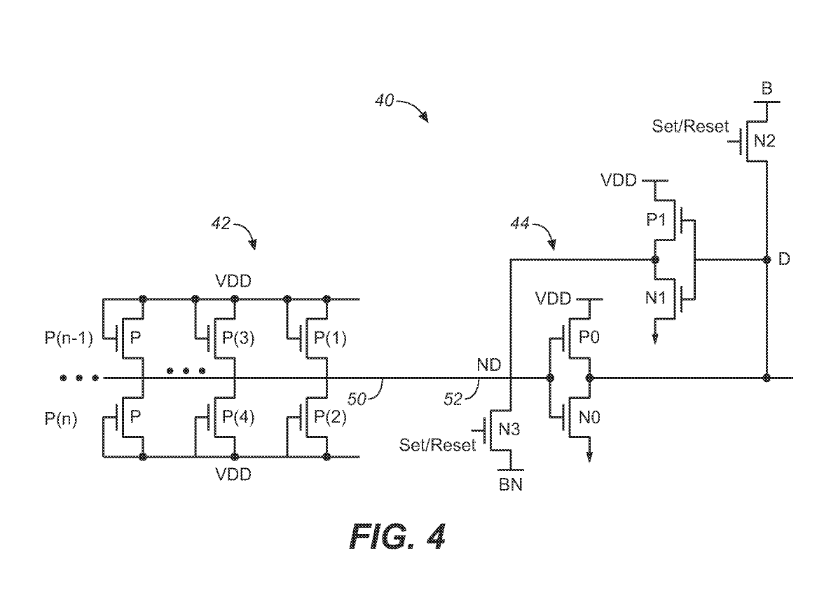

Latch 44 can include any type of memory element in any suitable technology. For example, latch 44 may include a memory element similar to a static random access memory (SRAM) element, a dynamic random access memory (DRAM) element, other types of random access memory elements, non-random access memory elements, charge coupled devices, charge injection devices, or other memory device structures. A particular example is described with reference to FIG. 4 below.

Neutron detection circuit 40 can further include a plurality of charged particle sensors 42 and respective latches 44, which are controlled by control circuit 46. Control circuit 46 can be configured to each read latch 44, log the results of the read, and re-set the latch at any desired frequency or pattern. For example, control circuit 46 may include an address generator, which automatically, or under processor control, generates a set of addresses that sequentially reads the states of the various latches 44, triggers an upset counter for each latch state reversal, and then re-sets the latch. The upset counter can be configured to count the number of detected “hits” over a predetermined time period and provide the count as an output to a monitor program or device.

Control circuit 46 can be implemented in hardware, software or a combination of both hardware and software. In one example, at least a portion or all of control circuit 46 is implemented as hardware in an integrated circuit. In another example, control circuit 46 includes a processor and a computer-implemented program stored on memory 48. The computer program includes instructions which when executed by the processor, configure the processor to perform the steps of the control function described herein. The instructions may be stored in or transmitted by computer-readable data medium 48. The medium may be non-transitory hardware storage medium that may be removable or non-removable, such as a compact disk read only memory (CD-ROM), a magnetic floppy disk, a hard disk, on-chip or off-chip random access memory. The medium may also comprise a transmission medium such as an electrical, optical, or radio signal, or a telecommunications network.

FIG. 4 is a schematic diagram illustrating in more detail an example of neutron detector circuit 40 as shown in FIG. 3, according to a particular example of the present disclosure. Circuit 40 includes charged particle sensor 42 (comprising a plurality of charged-sensitive elements such as biased semiconductor junctions) and a detection latch 44. Circuit 40 is fabricated on an integrated circuit in a manner such as that described with reference to FIGS. 2 and 3, for example, such that neutron conversion material is positioned in close proximity to one or more (for example all) of the biased semiconductor junctions contained in sensor 42 and detection latch 44. For example, an area consumed by the conversion material at least partially overlaps at least one of the area consumed by the plurality of semiconductor sense elements in sensor 42 or the area consumed by the latch.

Detection latch 44 includes two cross-coupled inverters formed by transistors P0/N0 and P1/N1. Node ND (latch input 52) is coupled to the input of inverter pair P0/N0 and to the output of inverter pair P1/N1. Node D (latch output 54) is coupled to the output of inverter pair P0/N0 and to the input of inverter pair P1/N1. N-type pass gate N2 has a drain coupled to a bit line B (which is used as a voltage bias input), a source coupled to output node D, and a gate coupled to control input SET/RESET. N-type pass gate N3 has a drain coupled to latch input node ND, a source coupled to bit line BN, and a gate coupled to control input SET/RESET.

Charged particle sensor 42 includes a plurality of P-type transistors labeled P(1) . . . P(n) coupled together in parallel, where “n” is a positive integer values greater than or equal to 1. In particular examples, “n” can be any integer greater than or equal to 2, less than or equal to infinity, less than or equal to 10 and/or less than or equal to 100, for example. The plurality of transistors P(1) to P(n) are coupled together in parallel and reverse-biased in an “off” state. Each of the transistors includes first and second terminals and a third, which controls current flow between the first and second terminals. In the case of a P-channel MOS transistor, the first and second terminals are referred to as a source and a drain, and the third terminal is referred to as a gate. In the example shown in FIG. 4, each of the transistors P(1) to P(n) has its gate and source coupled to a relatively positive power supply voltage bias node VDD and its drain coupled to sense output 50. In an alternative example, each gate is coupled to a voltage bias terminal having a voltage that is greater than VDD. Each of the transistors P(1) to P(n) is therefore biased in an “off” state, which blocks current from flowing from VDD to sense output 50.

During the “set” mode, control circuit 46 (shown in FIG. 3) places latch 44 in a “set” state in which node D has a logic HIGH (i.e., “1”) state, and node ND has a logic LOW (i.e., “0”) state. To place a “1” latch 44, which corresponds to a high voltage level VDD on node D, control circuit 46 applies a high voltage to bit line B and a low voltage to bit line BN. Control circuit 46 then applies a logic high voltage to the pass gate control input SET/RESET, which turns on transistors N2 and N3. This pulls node D high to VDD and pulls node ND low to a ground or zero voltage. The zero voltage on ND in turn forces the output of inverter pair P0/N0 on node D to be a high voltage, reinforcing the high voltage passed through N2. With a high voltage on node D2, inverter pair P1/N1 reinforces the low voltage on node ND. Control circuit 46 then returns the pass gate control input SET/RESET an inactive, low state, turning off pass gate transistors N2 and N3.

To read the state of latch 44, control circuit 46 precharges bit line B and BN to a logic high voltage, such as VDD, and applies a logic high voltage to pass gate control input SET/RESET. The bit lines B and BN, which are precharged high, are now left floating. With a “1” state in latch 44, the low voltage on node ND will slowly start to pull the voltage on bit line BN towards ground. Bit line B line will be pulled high by node D. A differential sense amplifier, not shown in FIG. 4, is used to sense a small voltage difference between bit lines B and BN. This improves the read speed. However, control circuit 46 can read the latch state in a variety of different ways, such as by sensing the state of a either one of bit lines B or BN with a single-ended amplifier or by reading node(s) D or ND directly, for example.

During the “sense” mode, latch 44 waits for detection of an ion hit. After setting latch 44 to a “high” state in the “set” mode, control circuit 46 places latch 44 in the sense mode by holding the pass gate control input SET/RESET low (turning off transistors N2 and N3) and holding bit lines B and BN high. In effect, this also precharges B and BN for a subsequent read.

As mentioned above, neutron detection circuit 40 includes a neutron conversion material, such as that shown in FIG. 1, positioned in close proximity to at least one of the charge-sensitive elements in sensor 42 or the latch 44. The neutron conversion material emits charged particles, such as alpha particles or Lithium ions, in response to a reaction of the material with a neutron. These charged particles may be detected by the charge-sensitive elements in sensor 42. As explained with reference to FIGS. 2A-2C, each of the PMOS transistors in sensor 42 also forms a parasitic bipolar transistor that is inactive during normal operation. However if a large enough charge is deposited on the body region of the transistor, caused by one or more of the emitted charged particles passing through the body region, this charge can turn “on” the parasitic bipolar transistor of a MOS transistor that is biased in the “off” state.

When one or more of the parasitic bipolar transistors in sensor 42 turns on, this permits current to flow from voltage bias node VDD to latch node ND. The resulting current can deposit enough charge on latch node ND to change the state of latch 44. In addition, the MOS transistors in latch 44, itself, that are biased in the “off” state” can detect the emitted charged particles in a similar manner as the transistors in sensor 42. Each of the transistors in latch 44 similarly includes a parasitic bipolar transistor that can become forward biased in response to a “hit” by the emitted charged particles into the body of the transistor. When forward biased, these parasitic bipolar devices can deposit a sufficient charge onto latch nodes ND and D or remove a sufficient charge from these nodes to override the state of the “on” MOS transistor in inverter pair P0/N0 or P1/N1, which can force the inverters to change states.

For example, assume a “1” is in the latch, node D is high and node ND is low. In this case, P0 is “on”, N0 is “off”, P1 is “off”, N1 is “on”, and N2 and N3 are “off”. A large ion hit on N0 would briefly turn on N0 and pull node D low. The low voltage on node D causes inverter P1/N1 to drive node ND to a high, thereby changing the state of the latch. Similarly, a large ion hit on P1 would briefly turn on P1, pulling node ND high, causing inverter P0/N0 to drive node D low, thereby changing the state of the inverter. A large ion hit on transistor N3 would turn on transistor N3, pulling node ND high and causing inverter P0/N0 to drive node D low to change the state of the latch. A hit on P0 would cause no upset since the drain and source of P0 are both at a high voltage of VDD, and P0 is already in an on state. A hit on N1 would cause no upset since the drain and source of N1 are both at a low voltage of GND and N1 is already in an on state. Also a hit on N2 would cause no upset since the drain and source of N2 are both at a high voltage of VDD.

The operation of the circuit shown in FIG. 4 thus illustrates an example of a method of detecting a neutron, according to an aspect of the present disclosure. As described above, a neutron conversion material emits charged particles in response to a reaction of the neutron conversion material to a neutron. The latch is initialized to a first state, and a plurality of semiconductor sense elements are biased in an OFF state. The semiconductor sense elements are configured to produce a sense current in response to the charged particles. The sense current changes the state of the latch from the first state to a second, different state. The present state of the latch is then read to detect the change from the first state to the second state.

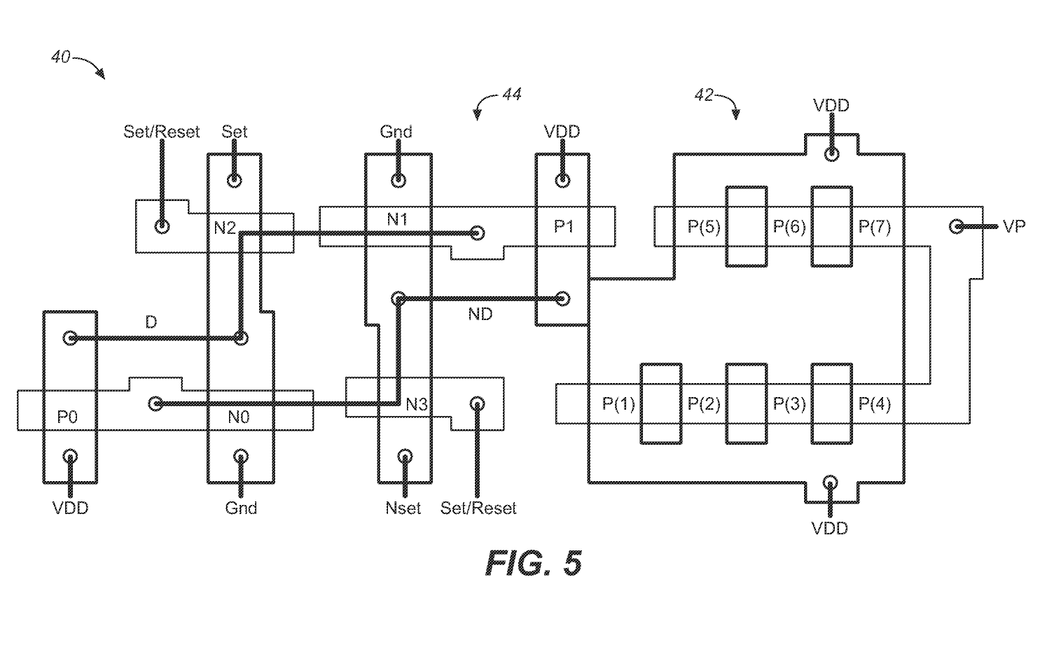

FIG. 5 is a diagram illustrating a physical layout of the neutron detection circuit shown in FIG. 4, which includes a sensor 42 of seven sensing elements (although only six are shown in FIG. 4) and a latch 44. The six transistors labeled N0, P0, N1, P1, N2, and N3 form latch 44, and the seven sense elements labeled P(1) to P(7) are connected to the latch. The number of sense elements connected to the latch can vary in different embodiments. One sense element or multiple sense elements in the form of PMOS transistors, NMOS transistors, or combinations of both can be connected to the latch, for example.

The efficiency of the latch is dependent on the area under the gates of the sense transistors. Based on measurements of detection circuit 40 in FIG. 4, the area of a single sense element is 1% of the overall area of the circuit. Previous semiconductor approaches have used an SRAM cell as the capture block with two of the six transistors acting as the sense elements. This produces a yield of approximately 2% efficiency, depending on the technology lithography, as defined by the sensitive area divided by the total area of the cell. Therefore approximately 98% of Alpha or Lithium ions would pass through the silicon, while missing a sensitive element, undetected. Simply making an array of SRAM cells larger does not improve the efficiency, it only increases the total area and the total power, limiting battery-operated life.

With the addition of a plurality of P-type sense elements, in this example seven sense elements, the detector circuit area is increased by only 90%. The sensitive area becomes 4.95 percent of the sense latch area. The sensitive area can be further increased with the addition of more sensitive elements. This represents a 2.5×-5× (for example) improvement to efficiency as compared with a typical 6-transistor SRAM, with marginal increases in power, yielding a much improved power per sensing area ratio, as shown in Table 1.

TABLE 1
Improved Sensing per unit area

| | Number of | | | | |
|---|---|---|---|---|---|
| Cell area | detecting | Sensitive | | | |
| (u2) | elements | area | % | Ratio | Comments |
| 1.15 | 1 | 0.0121 | 1.05 | 1 | Assumes that 1 transistor in Latch |
| 1.6575 | 4 | 0.0484 | 2.92 | 2.78 | is sensitive. |
| 1.8 | 6 | 0.0726 | 4.03 | 3.87 | Reorientation of devices has some |
| 1.957 | 8 | 0.0968 | 4.95 | 4.71 | Penalty. |
| 2.106 | 10 | 0.121 | 5.75 | 5.48 | Each 3 elements add .23u in the X. |
| | | | | | Can continue until the parasitics |
| | | | | | affect the Qcrit ability to capture |
| | | | | | the hit by a B10 alpha and Li ion. |

Technology chosen for this example = 90 nm SOI Starting latch cell is .65 by 1.515

The efficiency of detection is dependent on the sensitive area under the gates of the transistors that are sensitive to the ion upset mechanism. As described above with respect to FIG. 4, only three of the transistors within latch 44 can cause an upset for a specific data state. To increase the sensitive area for the detection of neutrons, a plurality of sense elements, such as parallel-connected, biased semiconductor junctions, can be added to the detection circuit. These semiconductor junctions can include, for example, a plurality of P-type sense transistors, N-type sense transistors, or both N and P type transistors. In the example shown in FIG. 4, a plurality of P-type transistors P(1) to P(n) are coupled to node ND. Sensor 42 can include any number of sense elements, such as 1 to 10 sense transistors. More than 10 sense elements can be used in other embodiments.

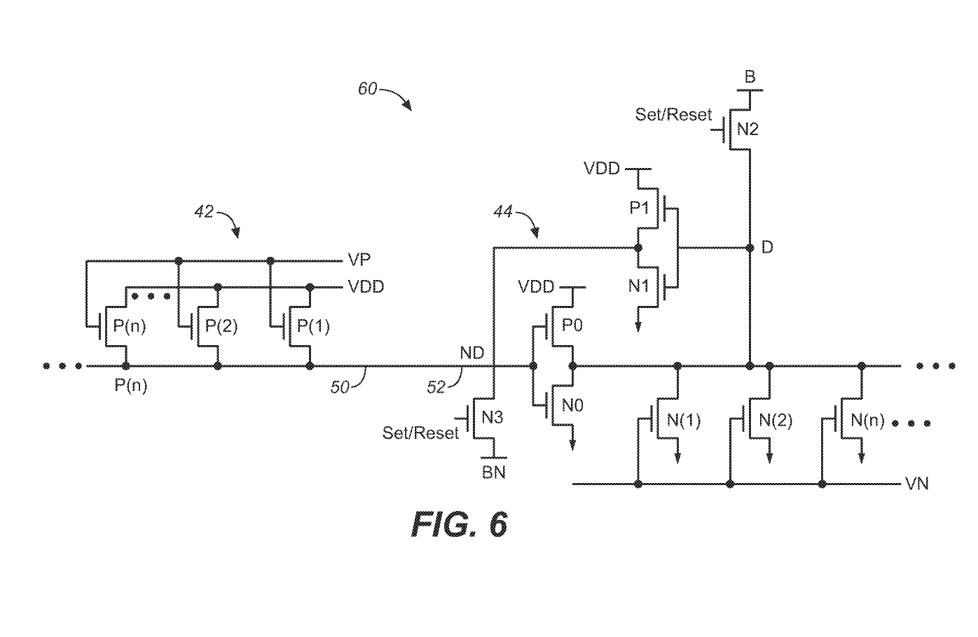

FIG. 6 illustrates a schematic diagram of a neutron detection circuit 60 according to an alternative embodiment of the disclosure. The same reference numerals are used in FIG. 6 as were used in FIG. 4 for the same or similar elements. Similar to the embodiment shown in FIG. 4, neutron detection circuit 60 includes a sensor 42 of P-type sense elements (labeled P(1) to P(n))) connected to node N, where)), where “n” is a positive integer value greater than or equal to 1. However, circuit 60 further includes an additional sensor 62 of sense elements connected to node D. In this example, the sense elements include a plurality of N-type transistors (labeled N(1) to N(m)), where “m” is a positive integer value greater than or equal to 1.

In this example, to reduce leakage current, transistors P(1) to P(n) have their drains connected to node ND, sources connected to voltage bias node VDD and gates connected to voltage bias node VP, which is a voltage higher than VDD. Similarly, transistors N(1) to N(m) have their drains connected to node D, sources connected to voltage bias node VSS and gates connected to voltage bias node VN, which is a voltage that is lower (or more negative) than VSS. However, the gates of P(1) to P(n) can be coupled to VDD, and the gates of N(1) to N(m) can be coupled to VSS.

During a detection operation, the P-type and N-type sense transistors in sensors 42 and 62 are off. A large ion hit on any of the sense transistors in sensors 42 and 62 would pull node ND high (or node D low) and cause inverters P0/N0 and P1/N1 to change state, thereby changing the state of latch 44.

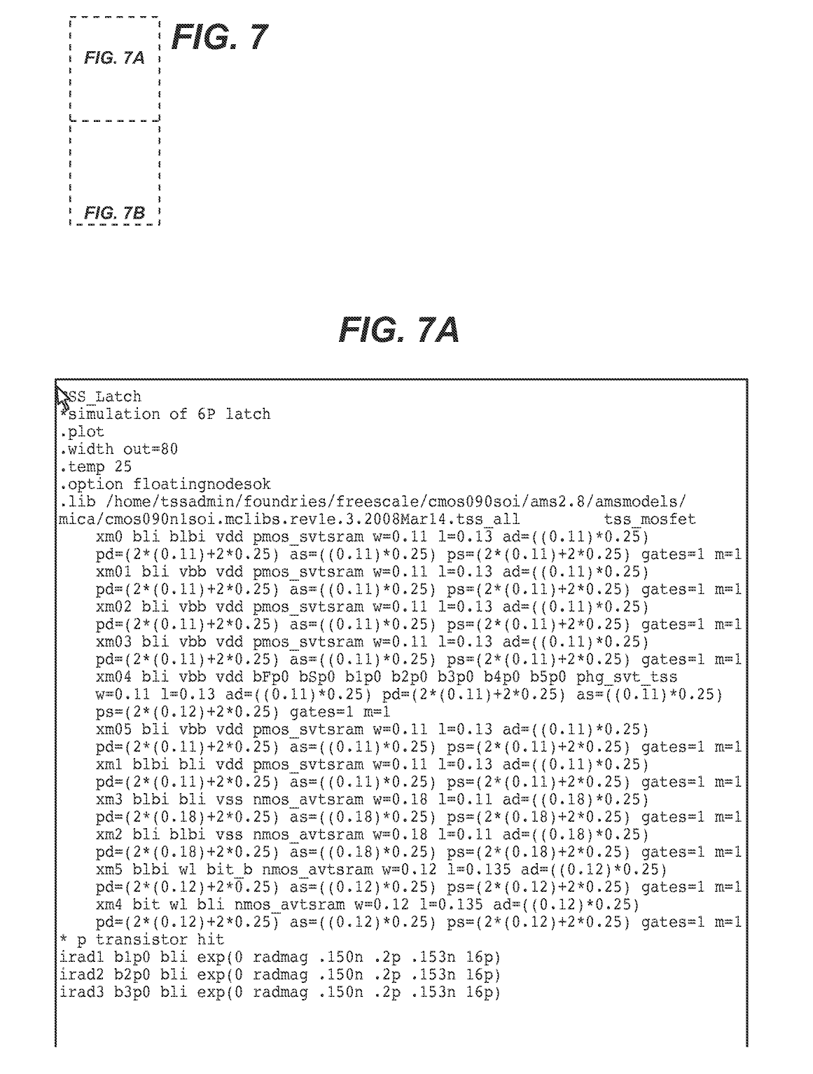

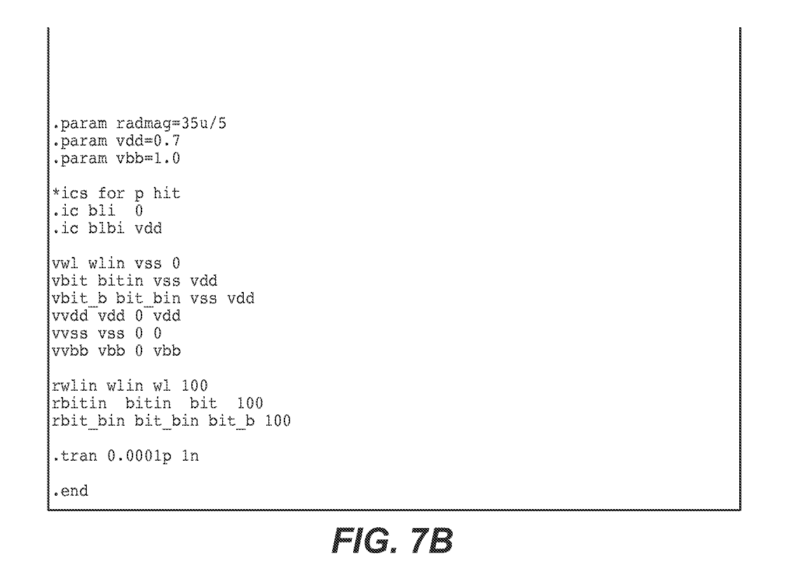

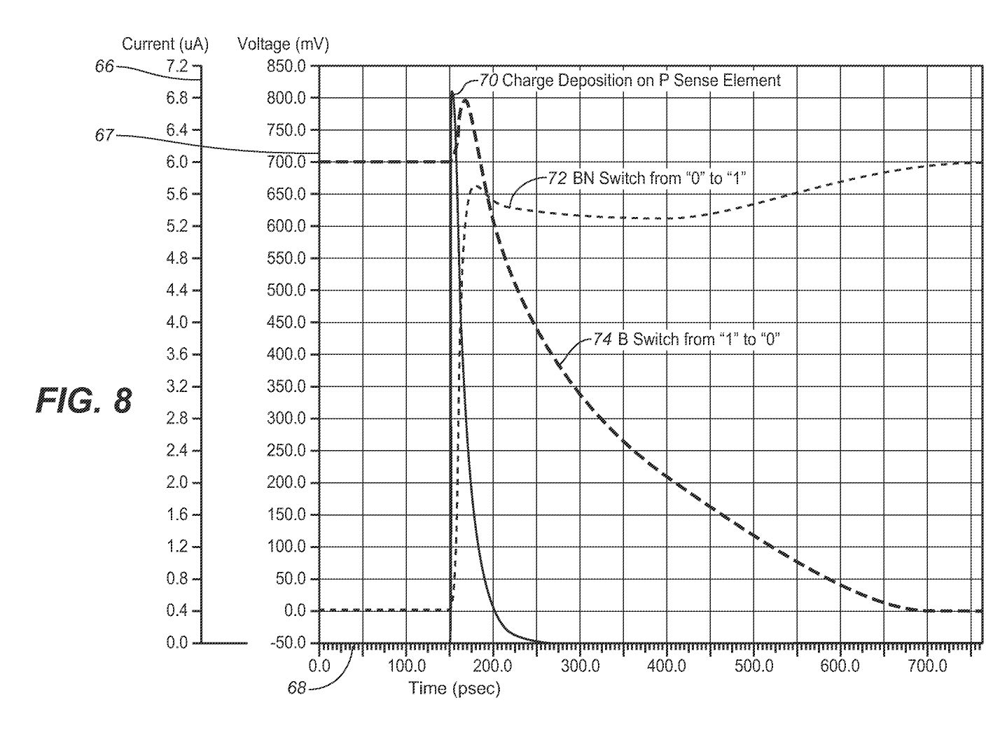

FIG. 7 illustrates a simulation file of the neutron detection circuit of FIG. 4. A plot of a hit on a single element in latch 44 (or in the sensor 42) is show in FIG. 8. The waveforms represent current and voltage on the vertical axes 66 and 67 as a function of time on the horizontal axis 68. Waveform 70 represents the charge deposited on one of the P-type sense elements, such as P1, at about 150 psec. Waveform 72 represents the resulting voltage change on latch node ND, from a “0” to a “1”. Waveform 74 represents the resulting voltage change on latch node D, from a “1” to a “0”. Thus, the state of latch 44 changes in response to an ion hit on one of the P-type sense transistors in the neutron detection circuit.

During detection operations, the neutron flux, or number of neutrons per unit area per unit of time, may be quite low due to various types of shielding. To improve the probability of detecting a neutron source, the number of sensing elements (e.g., biased semiconductor junctions) can be increased, which increases the sensing efficiency of the detector. A particular detection circuit 40 (or 60) may include, for example, ten sensing elements in sensors 42 and/or 62. In addition, a plurality of duplicated detection circuits similar to those shown in FIGS. 4 and 6 may be fabricated on one or more integrated circuit chips and interconnected together to provide millions to hundreds of millions of neutron sense elements, which greatly increases the probability of a Lithium ion or an alpha particle upsetting a latch, in other words changing the value of one of the latches from a 1 to a 0 (or from a 0 to a 1). The number of integrated circuits containing such detector circuits may also be increased in a detector system to further improve detection capability.

The additional neutron sense transistors provided by sensors 42 and 62 (shown in FIGS. 4 and 6) effectively increases the sensitive gate areas while minimizing the effect on normal latch operation. The sense transistors add junction capacitance to nodes D and ND, which adds delay to the switch time of the latch, and the latch area is increased with the added sense transistors, but the percentage of ion sensitive area versus latch area is also increased. As a result, the enhanced latch design provides a higher efficiency for ion detection than a standard 6-transistor SRAM memory element.

The Qcrit of an individual sense element is maintained even when the number of sense elements is increased. Each semiconductor technology will have a respective limit on the number of sense elements that can be added to a particular latch, in parallel with one another. With each added transistor, the increase in parasitic capacitance and leakage currents will finally limit the sense signal to the latch.

In addition to the plurality of sense elements, a further difference between the example shown in FIG. 4 and neutron detectors that use an SRAM cell is that SRAM cells are symmetrical in that whether they are set or reset, there is only one, or maybe two, devices that could alter the present data in the cell in response to a charged particle hit. The example shown in FIG. 4 is non-symmetrical because the sense transistors are based on a preset value in the latch. The sensing elements may be put on more than one circuit node, but are placed on “OFF” device nodes, for example. In a simple case, we set the value in the latch and put only P-FETs in parallel with the single “OFF” P-FET in the latch. The set value of the latch will change if one of the “OFF” P-FETs is hit with an ion.

An exemplary embodiment of the neutron detection circuit is particularly useful in a battery operated devices. The duration of battery life is primarily a function of the static current drawn by the plurality of sensing elements and the detection latch. As the ratio of sensing elements in the sensor to latches on the integrated circuit increases, the leakage current drawn by the plurality of sensing elements dominates the power dissipation. These currents include, for example, gate oxide leakage current, MOS sub-threshold leakage current, and reverse-biased diode leakage currents. Therefore, design and semiconductor processing improvements can be made for particular embodiments to lower the total static current, which would facilitate larger single arrays and systems with higher numbers of IC detector chips.

As discussed with respect to FIG. 6, the leakage current in the sensors can be reduced by connecting the gates of the P-type sense elements to a voltage that is higher than VDD and by connecting the gates of the N-type sense elements to a voltage that is lower than VN (ground). By raising the P-type gate voltage above the VDD source voltage, the leakage current is reduced by two to five times, for example. Similar leakage current reductions occur by pulling the N-type gate voltage below the ground level. Increasing the “off” gate voltages on the sensing elements effectively increases the threshold voltages Vt of the sense transistors without additional channel dopants that might degrade the parasitic bipolar Beta. This has the effect of reducing the sub-threshold leakage proportionally. The higher voltage source, requiring only gate oxide leakage current, can be generated in many ways including a charge coupled approach.

Using the reversed bias of the gate-controlled element allows a circuit designer the option to select from optimum commercially available Vt standards to further improve the sensing elements and their associated leakage as well as some other custom processing options. A further method of lowering leakage currents would be to reduce the core supply of the element. This supply can be theoretically reduced, for example, from the technology defined VDD to 2*Vt, for example, depending on the latch design.

The size and number of ion sense transistors that are connected to a single latch can be determined by the specific semiconductor (e.g., MOS) technology. As the size of the sense transistors increases, the ion sensing area increases the same amount. However the level of sensitivity is decreased. The area of the parasitic transistor can be optimized for detection of both alpha particles and Lithium ions. To further increase the latch ion sensitivity, additional sense transistors may be used. The number of sense transistors in the latch is only limited by the operation of the latch.

The attributes of the specific semiconductor technology will determine whether P-type sense transistors or N-type sense transistors are desired in the charged particle sensors. The parasitic pnp bipolar transistor in a P-type sense transistor may turn on with a lower ion charge than the parasitic npn bipolar transistor in an N-type sense transistor. Also the opposite case can occur, or both the npn and pnp may be equally sensitive.

Other semiconductor sensing elements may be used in place of the PMOS sense transistors and the NMOS sense transistors. Such elements include, for example, actual bipolar transistors or diodes, as appropriate for the chosen technology, which can be designed to be sensitive to particle currents.

### 4. Optimization by IC Processing

As mentioned in the previous section, the detection circuit may be optimized by design methods while still using the standard components of a commercially available process to match the sensing element specifically to capture the energy of the alpha particle and Lithium ion released by the neutron-B10 collision. Next, one could maximize the density of these elements on the collecting surface to facilitate the largest cross-sectional area of this collecting surface so that the probability of a neutron hitting the surface will be increased and that the probability of those neutrons that hit that surface will be detected. Further semiconductor processing improvements are available.

Exemplary process optimizations of the sensing element fall into two categories, those that improve the efficiency of the element and those that reduce the parasitic effects of the element. In one example, these improvements may be embodied by implementation on the sensing element alone leaving the standard commercial CMOS processing without change.

The reduction of parasitic effects is now described. By increasing the gate oxide on the sensing element by 2 to 4 Angstroms, for example, the gate oxide leakage current can be reduced by 1-2 decades, effectively eliminating that factor as a significant source of leakage current equation. Likewise, tailored implants would reduce the sub-threshold leakage of the sensing element.

An exemplary embodiment takes advantage of the floating body of an SOI semiconductor process. That floating body in a static condition for an “OFF” MOS transistor will float to a value equal to a weak forward-biased diode. This condition increases the leakage current of the transistor. As shown in Table 2, a properly sized body tie will reduce that leakage by 5× or greater. The physical size of the area for the implementation of that body tie must be considered to realize a net gain in efficiency.

TABLE 2
Improved Leakage with weak body tie

| Model | Width | Voltage | Length | Idrain | Igate | Isource |
|---|---|---|---|---|---|---|
| pmos_svtsram | 100 | 1 | 0.11 | 2.12E−08 | −7.04E−10 | −2.05E−08 |
| pmos_svtsram | 100 | 1 | 0.11 | 1.14E−08 | −4.84E−09 | −6.59E−09 |

1.86X Improvement in total current

A method of improving efficiency is now described. Tailoring the implants of the bipolar base region (the well) will also increase the effective Beta of the parasitic bipolar, lowering the Qcrit. Since the charge of the alpha and Li ion are well know, Qcrit margin can be translated into increased sensor sizes and efficiencies.

Since the amount of charge deposited in the silicon is directly proportional to the length of the path within the silicon, any increase in the base silicon layer thickness does play a role in the deposited charge. Any gains must be traded off negative process parameter changes.

### 5. Additional Examples of Semiconductor Structures Implementing a Neutron Conversion Layer

As discussed with reference to the Example shown in FIG. 1, semiconductor integrated circuit device 10 can include a neutron conversion layer 22, positioned above the active semiconductor layers 18 and the interconnect layer 20, wherein the interconnect layer is located between the conversion layer and the active semiconductor layer. In some embodiments, it may be desirable to position the neutron conversion layer in closer proximity to the active semiconductor layer.

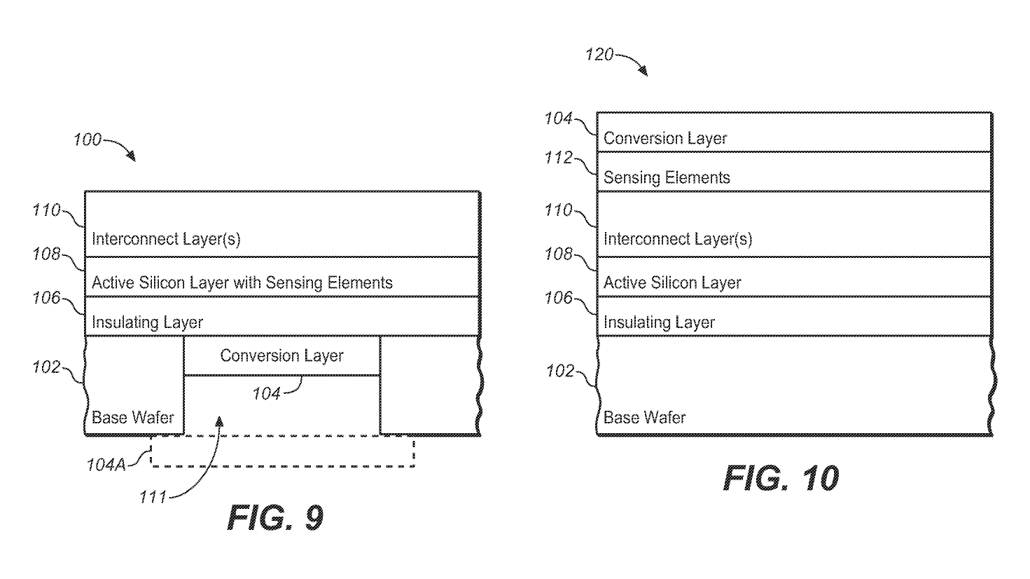

FIG. 9 is a simplified cross-sectional view of a neutron sensitive semiconductor integrated circuit device 100 in which the neutron conversion layer is located below the active semiconductor layer. In this example, semiconductor integrated circuit device 100 is a silicon-on-insulator (SOI) type device, which has a base silicon substrate 102, an insulating layer 106, an active semiconductor silicon device layer 108 with charge sensitive elements, and an interconnect layer 110. Various additional layers can also be included. The insulating layer 106 can include any suitable insulating material, such as silicon dioxide, which forms a buried oxide (BOX) that electrically isolates the active semiconductor device layer 108 from the base substrate 102. One or more neutron detection circuits such as those shown in FIGS. 4-6 are fabricated within active semiconductor device layer 108.

The neutron conversion layer 104 is positioned in close proximity to the active semiconductor device layer 108, such as in direct contact with 108 or separated by insulating layer 106 and/or a barrier layer. Neutron conversion layer 104 can cover the entire area of the integrated circuit chip or can cover only a portion of the chip area.

In the example shown in FIG. 9, neutron conversion layer 104 covers less than the entire chip area. Part of the base substrate layer 102 is removed, which creates a window 111 permitting the conversion layer 104 to be placed within window 111, directly on or close to insulating layer 106, as shown in the solid lines. In another example, neutron conversion layer 104 can be placed on window 111, as shown in dashed lines at 104A. This avoids the charged particles emitted from layer 104 from travelling through base substrate 102 to reach the charge-sensitive elements in active semiconductor layer 108.

At least a part of the area consumed by neutron conversion layer 104 overlaps at least a portion of the area consumed by the charge-sensitive elements in sensor 42 and/or those in latch 44 in the neutron detection circuit. In one example, window 111 is limited to the area consumed by the charge-sensitive elements in a particular neutron detection circuit, or a plurality of such circuits on a semiconductor chip.

The window 111 can be created by etching through the base substrate, down to insulating layer 106. Neutron conversion layer 104 can be positioned within window 111 by any suitable method such as be deposition or by placing a pre-fabricated conversion layer into or adjacent to window 111.

In an exemplary embodiment, the fabrication of device 100 is separated into two independent steps: fabrication of a sensing element structure and fabrication of a neutron conversion structure. The sensing element structure containing layers 102, 106, 108, and 110 can be prepared either at the wafer or die level, so that at completion, window 111 has been etched away from the active area of the charge-sensitive elements. The neutron conversion structure is created by combining a neutron conversion material on a separate base substrate. Once both structures are fabricated, they are then joined together to create neutron sensitive semiconductor integrated circuit device 100.

The assembly of neutron sensitive semiconductor integrated circuit device 100 is formed by joining the neutron conversion structure and the sensing element structure by use of an adhesive, for example. The neutron conversion structure (e.g., 104A) is placed such that it covers the cavity area of window 111 of the sensor structure and allows for a gap fill medium that has a low stopping power for charged particles. This gap fill medium can be a vacuum, air, or other low density gas which enables a long mean free path of alpha particles to minimize attenuation through the structure. It also can be filled with a suitable solid material. Assembly of the neutron detection sensor can be performed at the die or wafer level, for example.

In a particular example, neutron conversion layer 104/104A includes boron-10 and has a thickness of about 500 nm to 5000 nm. Other thicknesses can also be used. Conversion layer 104 can include, for example, a borosilicate glass film containing boron-10, or boron-10 can be implanted or diffused into insulating layer 106, for example.

FIG. 10 is a simplified cross-sectional view of a neutron sensitive semiconductor integrated circuit device 120 in which the plurality of sensing elements (such as in sensor 42 of FIG. 4, or sensor 42 and/or sensor 62 of FIG. 6) are positioned on a different layer than the active semiconductor devices that form the capture latch. In this example, the transistors forming latch 44 (in the example shown in FIG. 4) are fabricated on active semiconductor device layer 108. Interconnect layer 110 includes various individual layers and elements that electrically interconnect the semiconductor devices in a pattern to form a functioning latch. These interconnect elements can include polysilicon interconnects, metal layers, vias between layers, insulating layers, etc. The plurality of sensing elements (42 and/or 62) are fabricated on a layers 112 and electrically interconnected to the detection latch on layer 108 through vias of conductive material passing through interconnect layer 110. The neutron conversion layer 104 could be fabricated on top of the layer 112 of sensing elements. Again, further intermediate layers can be included, not shown in FIG. 10

This embodiment may further increase the detection efficiency in that the plurality of sensing elements can be physically located directly above the capture latch and not lose the efficiency related to the surface area of the latch. This approach would also expose the plurality of sensing elements to additional manufacturing processes relating to a Boron-10 conversion layer. Potential efficiencies of 50% would be possible. This embodiment could use a sensing material such as a PIN diode structures, thin-film poly transistors (TFT), or a CCD type device optimized to capture the alpha or Li ion charge, for example.

### 6. Neutron Detection Chip

In an illustrative embodiment, a neutron detection chip includes several millions of sense elements, detection latches, and corresponding address decoding, set control, error reading and counting, and Input/Output circuitry. In one example, the chip has two modes of operation, a neutron sense mode and a read mode. In the neutron sense mode, the detector latches are placed in a “1” state, and neutron sensing takes place over an extended period of time. In the read mode, the errors are read and counted on the chip by reading the state of each latch on the chip, and then the error count is read out of the chip in a serial mode, for example. An “error” corresponds to a latch that has its state changed from the initial “Set” state. Each of these errors represent the detection of a neutron “hit”. The chip can also be configured to include a test mode in which test circuitry (on or off the chip) sets “1s” in the latches and then reads the “1s” from the latches. The test circuitry then sets “0s” and reads “0s”. This test data is read out of the chip in a parallel mode, for example.

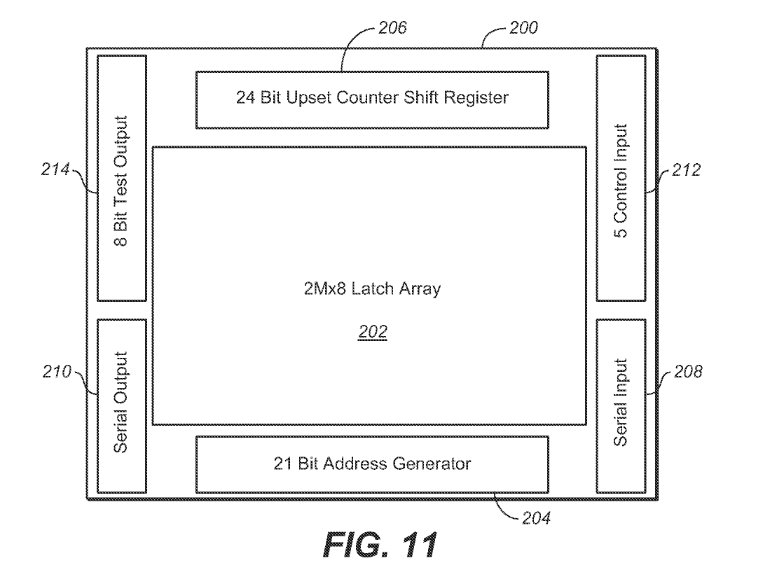

FIG. 11 is a diagram illustrating a neutron detection chip 200 according to an exemplary embodiment of the present disclosure. The neutron detection chip 200 can be used in applications that use multiple chips to provide a high neutron detection capability. To support such applications, chip 200 is designed to reduce the number of inputs/outputs (I/O). The amount of interconnect between chips is reduced and the density of chips is increased.

In this example, the architecture of chip 200 includes a plurality 202 of neutron detection circuits (each including a charged particle sensor and a corresponding detection latch), a 21-bit address generator 204, a counter shift register 206, a serial input 208, a serial output 210, a 5-bit control input 212, and an 8-bit test data output 214. Address generator 204 includes, for example, a Gray counter, which generates addresses for selecting the detection circuits (for “set” or read operations), so no external address lines are required and address switching is minimized. Only one data input line (Serial Input 208) is used to provide test capability to set or reset the latches. The 8-bit test data output 214 is used during wafer test and, in one embodiment, is not available for package test. Test output 214 can be used to perform a parallel data read at the die level for faster wafer level tests. A single data output (Serial Output 210) is includes serially outputting data, such as when reading the upset count from Upset counter shift register 206. The five input control signals (Control Input 212) are used to control the operation of the neutron detection chip. The chip also includes eight ground pins, four I/O voltage pins, four core voltage pins, and four sense voltage pins. Any other number or type of input and/or output pins can be included in other embodiments.

Neutron detection chip 200 can be fabricated to include any number of latches, such as 16 million latches, 32 million latches, or more, depending on the technology. The example shown in FIG. 11 is organized to include 2 million words of 8 latches each, for a total of 16 million neutron detection latches. Each read of the latches on chip 200 has the possibility of having from 0 to 8 upsets in each word. Upset counter shift Register 206 adds the upsets from each read to generate an overall upset count. This upset count is stored in the counter or in another memory element on the chip, for example. At the end of the read operation, or at any other desired time, the error count can be serially read off-chip upon a command provided to the chip through control inputs 212 or under program control on the chip, for example. In one example, the upset counter is capable of counting 16 million upset counts. The upset counter greatly facilitates the use of the neutron detector chip by providing more on-chip analysis capability and simplifying the interface.

The chip interface may be designed to be command driven by a microprocessor, which is connected to the detection chip through the control input. The microprocessor generates a clock and four other control signals that are provided to the detection chip and receives from the chip the upset count and/or the upset data (contents read from the latches) through the Serial Output 210. The low number of signal pins on the neutron detection chip allows a microprocessor to control several chips in parallel.

The microprocessor control also can provide the capability to manage power consumption while the neutron detection chip is in the neutron sense mode. The microprocessor can be programmed to reduce the power supply voltages supplied to the detection chip to lower the standby current and prolong battery life. An added benefit of the voltage control is that it permits control over the sensitivity of the sense element in the neutron sense latch. A reduction of the voltage between the source and drain of the sense element improves the sensitivity of the sense element. An increase of the gate voltage relative to the source voltage reduces the sub-threshold leakage of the sense element.

Although the present disclosure has been described with reference to one or more examples, workers skilled in the art will recognize that changes may be made in form and detail without departing from the scope of the disclosure and/or the appended claims.

What is claimed is:

1. A neutron detector comprising:
a neutron conversion material that emits charged particles in response to a reaction with neutrons;
a sensor comprising a plurality of semiconductor sense elements electrically connected together in parallel, which are sensitive to the charged particles; and
a latch coupled to an output of the sensor.

2. The neutron detector of claim 1, wherein the plurality of semiconductor sense elements comprises a plurality of reverse-biased semiconductor junctions coupled together in parallel.

3. The neutron detector of claim 1, wherein the plurality of semiconductor sense elements comprises a plurality of P-channel or N-channel transistors coupled together in parallel and biased in an “OFF” state.

4. The neutron detector of claim 1, wherein the latch comprises cross-coupled inverters having first and second nodes of opposite logic states, and wherein the sensor comprises:
a plurality of P-channel transistors coupled together in parallel and having a first output connected to the first node of the latch; and
a plurality of N-channel transistors coupled together in parallel and having a second output connected to the second node of the latch.

5. The neutron detector of claim 1, wherein:
the plurality of semiconductor sense elements comprises a plurality of transistors coupled together in parallel between a voltage bias node and the sensor output and biased in an “OFF” state, which blocks current from flowing between the voltage bias node and the sensor output; and
each of the transistors comprises a body and a parasitic transistor having a parasitic current-control terminal formed by the body, which is configured to become forward biased in response to the charged particles.

6. The neutron detector of claim 1, further comprising a first voltage bias node and wherein:
the plurality of semiconductor sense elements comprises a plurality of transistors coupled together in parallel with one another, wherein each transistor comprises a first terminal connected to the first voltage bias node, a second terminal connected to the sensor output, and a third, current-control terminal, which controls current flow between the first and second terminals and is coupled to the first voltage bias node.

7. The neutron detector of claim 1, further comprising first and second voltage bias nodes and wherein:
the plurality of semiconductor sense elements comprises a plurality of N-type or P-type transistors coupled together in parallel with one another, wherein each transistor comprises a first terminal connected to the first voltage bias node, a second terminal connected to the sensor output, and a third, current-control terminal, which controls current flow between the first and second terminals and is coupled to the second voltage bias node;
in the case of the plurality of transistors being N-type transistors, the second voltage bias node is biased at a more negative voltage than the first voltage bias node; and
in the case of the plurality of transistors being P-type transistors, the second voltage bias node is biased at a more positive voltage than the first voltage bias node.

8. The neutron detector of claim 1, wherein the latch comprises:
a control input;
cross-coupled inverters having first and second nodes of opposite logic states;
first and second bit lines;
a first pass gate coupled between the first node and the first bit line; and
a second pass gate coupled between the second node and the second bit line, the first and second pass gates having control terminals coupled to the control input.

9. The neutron detector of claim 1, wherein the conversion material comprises a material that emits at least one of alpha particles or Lithium ions in response to a neutron passing through the conversion material.

10. The neutron detector of claim 1, further comprising:
a plurality of sensors, each comprising a plurality of semiconductor sense elements electrically connected together in parallel, which are sensitive to the charged particles and have a corresponding output; and
a plurality of latches, each latch being coupled to the output of a respective one of the sensors.

11. A semiconductor substrate comprising:
a neutron conversion layer that emits charged particles in response to a reaction with neutrons;
an active semiconductor device layer comprising at least one latch having a latch input; and
a sensor comprising a plurality of semiconductor sense elements, which are electrically connected together in parallel, are sensitive to the charged particles, and have an output connected to the latch input.

12. The semiconductor substrate of claim 11, wherein the plurality of semiconductor sense elements is fabricated within the active semiconductor device layer.

13. The semiconductor substrate of claim 11, wherein the plurality of semiconductor sense elements is fabricated in a layer of the semiconductor substrate that is between the neutron conversion layer and the active semiconductor device layer.

14. The semiconductor substrate of claim 13, wherein an area consumed by the plurality of semiconductor sense elements at least partially overlaps an area consumed by the latch.

15. The semiconductor substrate of claim 11, wherein the plurality of semiconductor sense elements comprises a plurality of reverse-biased semiconductor junctions coupled together in parallel.

16. The semiconductor substrate of claim 11, wherein the plurality of semiconductor sense elements comprises a plurality of P-channel or N-channel transistors coupled together in parallel and biased in an “OFF” state.

17. The semiconductor substrate of claim 11, wherein the latch comprises cross-coupled inverters having first and second nodes of opposite logic states, and wherein the sensor comprises:
a plurality of P-channel transistors coupled together in parallel and having a first output connected to the first node of the latch; and
a plurality of N-channel transistors coupled together in parallel and having a second output connected to the second node of the latch.

18. The semiconductor substrate of claim 11, wherein:
the plurality of semiconductor sense elements comprises a plurality of transistors coupled together in parallel between a voltage bias node and the output and biased in an “OFF” state, which blocks current from flowing between the voltage bias node and the output; and
each of the transistors comprises a body and a parasitic transistor having a parasitic current-control terminal formed by the body, which is configured to become forward biased in response to the charged particles.

19. The semiconductor substrate of claim 11, further comprising a first voltage bias node and wherein:
the plurality of semiconductor sense elements comprises a plurality of transistors coupled together in parallel with one another, wherein each transistor comprises a first terminal connected to the first voltage bias node, a second terminal connected to the sensor output, and a third, current-control terminal, which controls current flow between the first and second terminals and is coupled to the first voltage bias node.

20. The semiconductor substrate of claim 11, further comprising first and second voltage bias nodes and wherein:
the plurality of semiconductor sense elements comprises a plurality of N-type or P-type transistors coupled together in parallel with one another, wherein each transistor comprises a first terminal connected to the first voltage bias node, a second terminal connected to the sensor output, and a third, current-control terminal, which controls current flow between the first and second terminals and is coupled to the second voltage bias node;
in the case of the plurality of transistors being N-type transistors, the second voltage bias node is biased at a more negative voltage than the first voltage bias node; and
in the case of the plurality of transistors being P-type transistors, the second voltage bias node is biased at a more positive voltage than the first voltage bias node.

21. The semiconductor substrate of claim 11, wherein the latch comprises:
a control input;
cross-coupled inverters having first and second nodes of opposite logic states;
first and second bit lines;
a first pass gate coupled between the first node and the first bit line; and
a second pass gate coupled between the second node and the second bit line, the first and second pass gates having control terminals coupled to the control input.

22. The semiconductor substrate of claim 11, wherein the neutron conversion layer comprises a material that emits at least one of alpha particles or Lithium ions in response to a neutron passing through the neutron conversion layer.

23. The semiconductor substrate of claim 11, further comprising:
a plurality of sensors, each comprising a plurality of semiconductor sense elements that electrically connected together in parallel that are sensitive to the charged particles and have a corresponding output; and
a plurality of latches, each latch being coupled to the output of a respective one of the sensors.

24. A method of detecting a neutron, comprising:
emitting charged particles from a neutron conversion material in response to a reaction of the neutron conversion material to a neutron;
initializing a latch to a first state;
biasing a plurality of semiconductor sense elements in an OFF state, the semiconductor sense elements being configured to produce a sense current in response to the charged particles;
changing the latch from the first state to a second, different state using the sense current; and
reading a present state of the latch to detect the change from the first state to the second state.
